(19) United States
(12) Patent Application Publication
(10) Pub. No.: US 2017/0011912 A1
(43) Pub. Date: Jan. 12, 2017

(54) SEMICONDUCTOR ASSEMBLIES WITH FLEXIBLE SUBSTRATES

(71) Applicant: INTEL CORPORATION, Santa Clara, CA (US)

(72) Inventors: Niloy MUKHERJEE, Portland, OR (US); Brian S. DOYLE, Portland, OR (US); Marko RADOSAVLJEVIC, Beaverton, OR (US); Ravi PILLARISETTY, Portland, OR (US); Han Wui THEN, Portland, OR (US); Valluri R. RAO, Saratoga, CA (US); Robert S. CHAU, Beaverton, OR (US)

(21) Appl. No.: 15/119,683

(22) PCT Filed: Mar. 18, 2014
(86) PCT No.: PCT/US2014/031094

§ 371 Date: Aug. 17, 2016

(51) Int. Cl. H01L 21/02; H01L 29/786; H01L 27/12

(52) U.S. Cl. CPC H01L 21/02513; H01L 21/02488; H01L 21/02595; H01L 21/02428; H01L 21/02422; H01L 21/02549; H01L 21/02631; H01L 21/02675; H01L 27/1225; H01L 27/1218; H01L 29/78603; H01L 29/78681; H01L 21/02532; H01L 21/02551; H01L 21/02538; H01L 21/0228; H01L 21/02282; H01L 21/02186; H01L 21/02178; H01L 21/02164

(57) ABSTRACT

Embodiments of semiconductor assemblies, and related integrated circuit devices and techniques, are disclosed herein. In some embodiments, a semiconductor assembly may include a flexible substrate, a polycrystalline semiconductor material, and a polycrystalline dielectric disposed between and adjacent to the flexible substrate and the polycrystalline semiconductor material. The polycrystalline semiconductor material. The polycrystalline semiconductor material may include a polycrystalline III-V material, a polycrystalline II-VI material or polycrystalline germanium. Other embodiments may be disclosed and/or claimed.

### TECHNICAL FIELD

The present disclosure relates generally to the field of semiconductor devices, and more particularly, to semiconductor assemblies with flexible substrates.

### BACKGROUND

Some attempts have been made to develop flexible electronic circuits for use in wearable and other devices. In these devices, flexibility has typically been obtained at the expense of electrical performance. High performance, single crystalline semiconductors may not be readily grown on typical, amorphous flexible substrates. Additionally, because the substrates used in existing flexible electronic circuits are unable to withstand high processing temperatures, only semiconductor materials with low processing temperatures have been used; because these materials typically have lower performance than materials with high processing temperatures, electrical performance of flexible electronic circuits has been limited.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 is a graph illustrating processing temperature constraints for the integration of various semiconductor materials and various flexible substrates.

FIG. 2 is an exploded side view of a semiconductor assembly, in accordance with various embodiments.

FIGS. 3-7 are side views of various stages in a process for manufacturing the semiconductor assembly of FIG. 2, in accordance with various embodiments.

FIG. 8 is a cross-sectional view of a portion of an integrated circuit (IC) device which may include one or more of the semiconductor assemblies disclosed herein, in accordance with some embodiments.

FIG. 9 is a flow diagram of an illustrative process for manufacturing an IC device including a semiconductor assembly, in accordance with various embodiments.

FIG. 10 schematically illustrates a computing device that may include one or more semiconductor assemblies as disclosed herein, in accordance with various embodiments.

### DETAILED DESCRIPTION

Embodiments of semiconductor assemblies, and related integrated circuit devices and techniques, are disclosed herein. In some embodiments, a semiconductor assembly may include a flexible substrate, a polycrystalline semiconductor material, and a polycrystalline dielectric disposed between and adjacent to the flexible substrate and the polycrystalline semiconductor material. The polycrystalline semiconductor material may include a polycrystalline III-V material, a polycrystalline II-VI material or polycrystalline germanium.

The semiconductor assemblies and related techniques disclosed herein may enable the formation of transistor device layers on flexible substrates with improved performance properties over existing flexible substrate integrated circuit (IC) devices. In particular, the semiconductor assemblies and related techniques disclosed herein may enable the direct deposit or growth of polycrystalline III-V material, polycrystalline II-VI material or polycrystalline germanium on a flexible substrate.

In some embodiments, these polycrystalline semiconductor materials may have a greater electron mobility than semiconductor materials currently used with flexible substrates (such as amorphous semiconductor materials or polycrystalline silicon). An improved electron mobility may result in improved electrical performance of a transistor formed on the semiconductor assembly.

In some embodiments, these polycrystalline semiconductor materials may be processed at lower temperatures than other semiconductor materials with similar electrical performance (e.g., similar electron mobility). In particular, the maximum temperature needed during processing of these materials (e.g., in the growth or anneal phases) may be lower than other semiconductor materials with similar electrical performance. Consequently, flexible substrates that may melt, deform or otherwise degrade at the processing temperatures required for these other semiconductor materials may be used with the polycrystalline semiconductor materials disclosed herein. This may enable the use of new flexible substrate materials in IC devices without substantially sacrificing electrical performance.

In the following detailed description, reference is made to the accompanying drawings which form a part hereof wherein like numerals designate like parts throughout, and in which is shown by way of illustration embodiments that may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order than the described embodiment. Various additional operations may be performed and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description uses the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

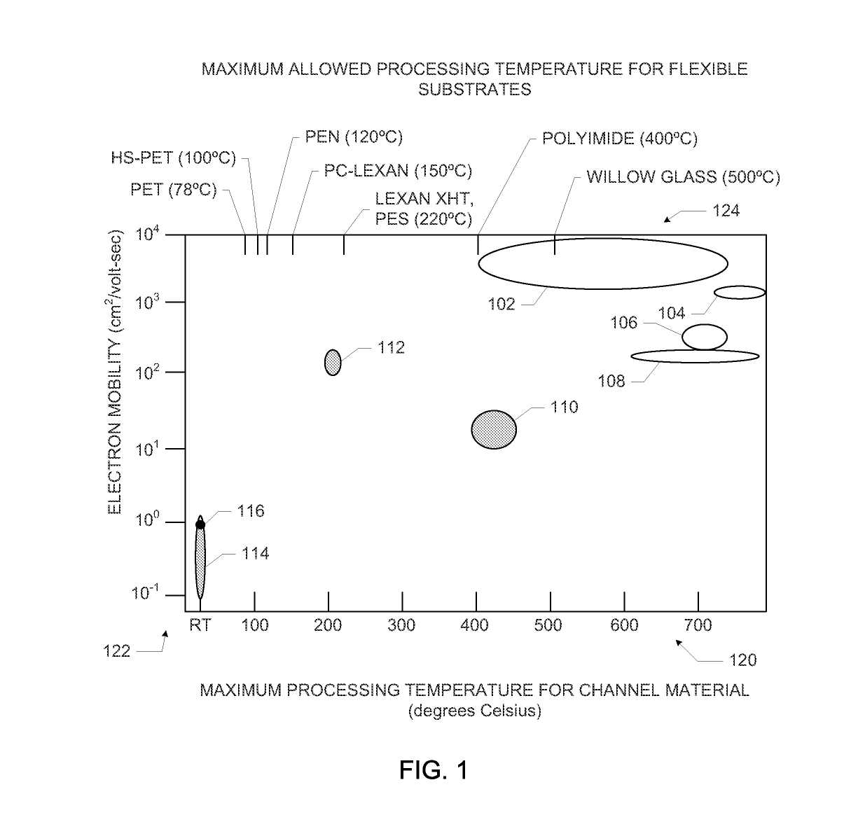

FIG. 1 is a graph illustrating processing temperature constraints for the integration of various semiconductor materials and various flexible substrates. The first x-axis 120 represents the maximum temperature typically required during the processing of various semiconductor materials for use in a transistor channel (e.g., during epitaxy and anneal). The y-axis 122 represents the electron mobility of the semiconductor material after processing. Ranges for a number of semiconductor materials are illustrated in FIG. 1, including single crystal III-V materials 102, single crystal III-nitride materials 104, single crystal silicon nanomembrane materials 106, transition metal dichalcogenides 108, amorphous oxides 110 (such as indium gallium zinc oxide), polycrystalline silicon 112 (e.g., low-temperature polycrystalline silicon), polymers 114 (such as pentacene) and amorphous silicon 116 (such as hydrogenated amorphous silicon). Some of these materials may be formed by direct growth or deposition (such as the materials 102, 104, 106 and 108) and others by layer transfer (such as the materials 110, 112 and 114). The materials in the upper right-hand corner of the graph of FIG. 1 may be single crystal materials, which do not include grain boundaries that may cause scattering of electrons, and which consequently may have high electrical performance.

The second x-axis 124 represents the approximate maximum allowed processing temperature for various flexible substrate materials. A number of flexible substrate materials are illustrated in FIG. 1, including examples of polyethylene terephthalate (PET, 78 degrees Celsius), heat-stabilized PET (HS-PET) (100 degrees Celsius), polyethylene naphthalate (PEN, 120 degrees Celsius), polycarbonate resin amorphous thermoplastic polymer (such as PC-LEXAN, 150 degrees Celsius), high heat polycarbonate copolymer (such as LEXAN XHT, 220 degrees Celsius), polyethersulfone (PES, 220 degrees Celsius), polyimide (such as KAPTON, 400 degrees Celsius) and flexible glass (such as an alkali-free borosilicate, e.g. WILLOW GLASS, 500 degrees Celsius).

FIG. 1 indicates that many semiconductor materials require processing temperatures that are beyond the maximum allowed processing temperature for many flexible substrate materials. In particular, higher performance semiconductor materials (e.g., those with the greatest electron mobility) often require particularly high maximum processing temperatures, leaving few if any options for temperature-compatible flexible substrate materials. FIG. 1 also indicates that semiconductor materials that are temperature-compatible with several flexible substrate materials are typically the lower performance semiconductor materials (e.g., those with the lowest electron mobility).

Embodiments of the semiconductor assemblies disclosed herein may include polycrystalline semiconductor materials that are temperature compatible with many flexible substrate materials (e.g., by having a maximum processing temperature less than 400 degrees Celsius) while having improved electrical performance over existing “low temperature” semiconductor materials. In particular, the polycrystalline semiconductor materials disclosed herein may have temperature and performance characteristics closer to the upper left hand corner of the graph of FIG. 1 than many existing semiconductor materials (or indeed, to amorphous forms of III-V, II-VI or germanium materials). Although the grain boundaries of polycrystalline semiconductor materials may cause electrons to scatter, this scattering may be more limited than in amorphous materials, and thus polycrystalline semiconductor materials may exhibit improved performance over such amorphous materials.

In some embodiments, the polycrystalline semiconductor materials of the semiconductor assemblies disclosed herein may be formed on a polycrystalline dielectric. The grain boundaries of the polycrystalline dielectric may provide nucleation sites for the formation of grains of the polycrystalline semiconductor. These nucleation sites may be high-energy sites at which formation of a crystallized grain in the semiconductor material would reduce the local energy. Thus, control of the grains of the polycrystalline dielectric may result in control of the grains of the polycrystalline semiconductor material. Existing deposition techniques with flexible substrates typically deposit a semiconductor material directly on the flexible substrate. When the flexible substrate is amorphous (as they typically are), the nucleation sites provided by the flexible substrate are irregular; thus, any crystallization that takes place after deposition of a semiconductor material on an amorphous substrate may also be irregular, and may not exhibit the advantageous electrical properties of polycrystalline or crystalline semiconductor materials. Attempts to “regularize” the crystal structure of the semiconductor material after deposition on the flexible substrate may require temperatures higher than flexible substrate is able to withstand.

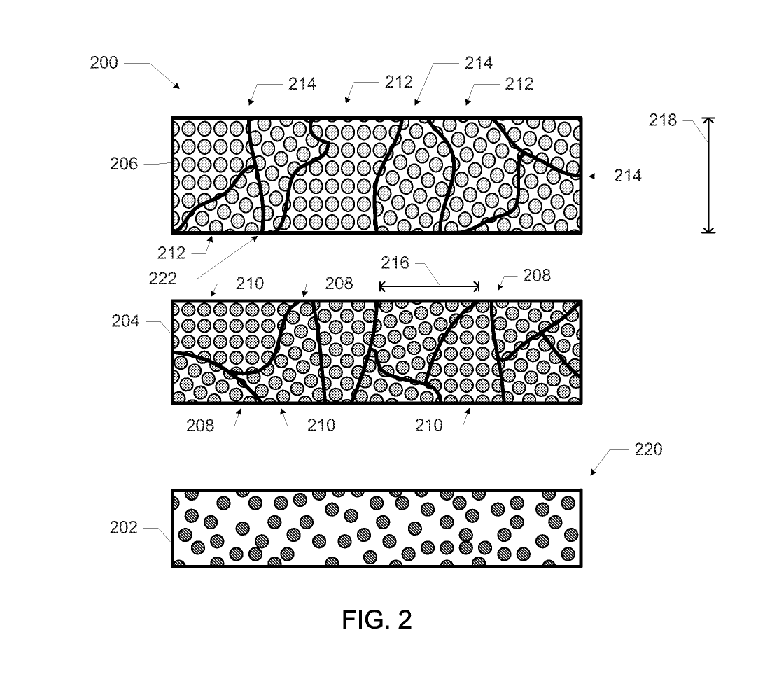

FIG. 2 is an exploded side view of a semiconductor assembly 200, in accordance with various embodiments. The semiconductor assembly 200 may include a flexible substrate 202, a polycrystalline dielectric 204, and a polycrystalline semiconductor material 206. The polycrystalline dielectric 204 may be disposed between the flexible substrate 202 and the polycrystalline semiconductor material 206, and may be adjacent to a surface 220 of the flexible substrate 202 and a surface 222 of the polycrystalline semiconductor material 206.

The flexible substrate 202 may be formed from any flexible substrate material desirable for flexible electronic applications. For example, in some embodiments, the flexible substrate 202 may be formed from one or more of polyethylene terephthalate, polyethylene naphthalate, polycarbonate material, polyethersulfone material, polyimide material, or alkali-free borosilicate. In some embodiments, the flexible substrate 202 may be an amorphous material (e.g., one whose constituent molecules are not arranged regionally or wholly in a regular pattern).

In some embodiments, the flexible substrate 202 may have a maximum processing temperature that is less than 400 degrees Celsius. This maximum processing temperature may represent a temperature beyond which the flexible substrate 202 cannot maintain its desired properties. For example, in some embodiments, the flexible substrate 202 may have a melting temperature less than 400 degrees Celsius.

The polycrystalline dielectric 204 may be formed from any dielectric material that may be formed with a polycrystalline structure (e.g., a structure with regional regular arrangement of the constituent molecules). For example, in some embodiments, the polycrystalline dielectric 204 may include one or more of titanium dioxide, silicon dioxide or aluminum oxide. The polycrystalline dielectric 204 may include multiple grains 210, with each grain formed of a substantially regular arrangement of constituent molecules. The grains 210 of the polycrystalline dielectric 204 may be separated by grain boundaries 208. The grain boundaries 208 may represent the interface between grains 210 having different molecular arrangement orientations.

The illustration in FIG. 2 of the grains 210 and the grain boundaries 208 of the polycrystalline dielectric 204 are figurative, and the sizes and shapes of the grains 210 and the grain boundaries 208 may vary between different dielectric materials and fabrication processes. In some embodiments, the spacing 216 between at least some of the grain boundaries 208 of the polycrystalline dielectric 204 may be on the order of approximately 50 nanometers to approximately 200 nanometers.

The polycrystalline semiconductor material 206 may be formed from any semiconductor material capable of being arranged in a polycrystalline structure. For example, in some embodiments, the polycrystalline semiconductor material 206 may include a polycrystalline III-V material, a polycrystalline II-VI material or polycrystalline germanium. For example, the polycrystalline semiconductor material 206 may include indium antimonide, indium gallium nitride, or indium nitride. Embodiments in which the polycrystalline semiconductor material 206 includes a polycrystalline II-VI material may be particularly advantageous for optoelectronic applications.

The polycrystalline semiconductor material 206 may include multiple grains 212, with each grain formed of a substantially regular arrangement of constituent molecules. The grains 212 the polycrystalline semiconductor material 206 may be separated by grain boundaries 214. The grain boundaries 214 may represent the interface between grains 212 having different molecular arrangement orientations. In some embodiments, the grain boundaries 208 of the polycrystalline dielectric 204 may provide nucleation sites for the formation of the grains 212 of the polycrystalline semiconductor material 206.

The polycrystalline semiconductor material 206 may be formed so as to have different electrical, physical and/or optical properties. In some embodiments, a thickness 218 of the polycrystalline semiconductor material 206 may be between approximately 5 nanometers and approximately 250 nanometers. In some embodiments, a thickness 218 of the polycrystalline semiconductor material 206 may be 500 nanometers or greater. In some embodiments, a sheet resistance of the polycrystalline semiconductor material 206 may be less than 2000 ohms per square (e.g., for a polycrystalline semiconductor material having a thickness of approximately 500 nanometers). The sheet resistance may be an improvement over a sheet resistance of an amorphous form of the polycrystalline semiconductor material 206. For example, the sheet resistance of an amorphous form of the polycrystalline semiconductor material 206 may be greater than 3000 ohms per square (e.g., for a polycrystalline semiconductor material having a thickness of approximately 500 nanometers).

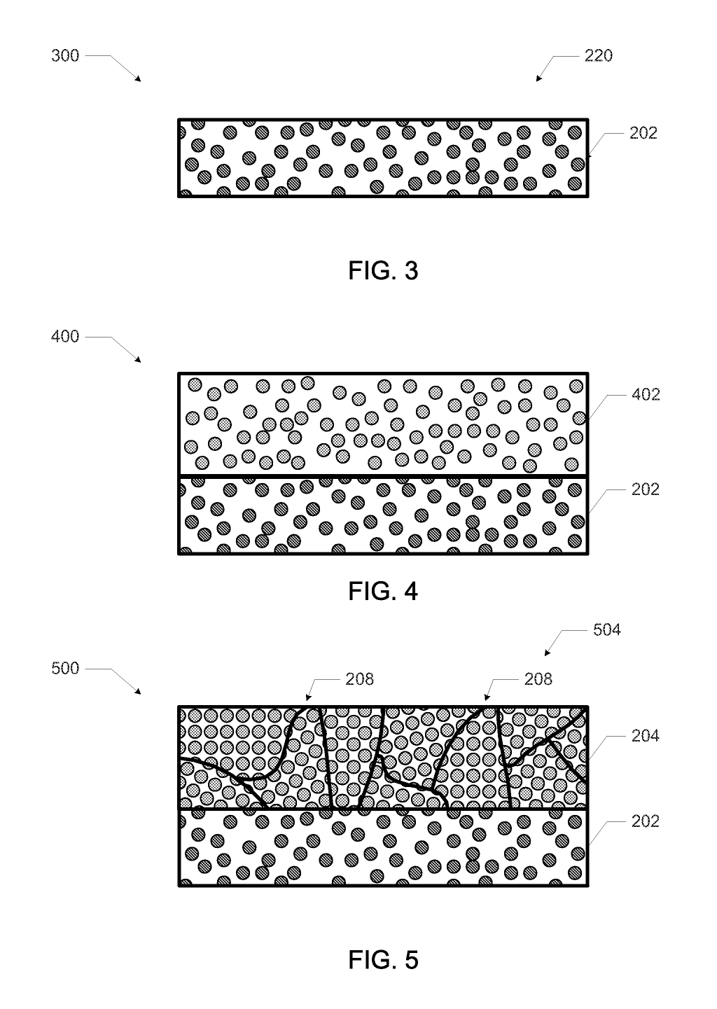

FIGS. 3-7 are side views of various stages in a process for manufacturing the semiconductor assembly 200, in accordance with various embodiments.

FIG. 3 depicts an assembly 300 formed after a flexible substrate 202 is provided. The flexible substrate 202 may take the form of any of the embodiments discussed above with reference to FIG. 2. For example, in some embodiments, the flexible substrate 202 may be an amorphous material. The flexible substrate 202 may have an exposed surface 220.

FIG. 4 depicts an assembly 400 formed after a dielectric 402 is deposited on the surface 220 of the flexible substrate 202. In some embodiments, the dielectric 402 may be an amorphous material at the time of deposition, and may be subsequently processed to transform the dielectric 402 into a polycrystalline dielectric (as discussed below with reference to FIG. 5). For example, the dielectric 402 may be an amorphous dielectric spun onto the flexible substrate 202 using a conventional spin coating technique. In some embodiments, the dielectric 402 may be in polycrystalline form at the time of or substantially at the time of deposition, and thus may not need much or any further processing to form a polycrystalline dielectric. For example, in some embodiments, the dielectric 402 may be a polycrystalline dielectric formed by atomic layer deposition (ALD).

FIG. 5 depicts an assembly 500 formed after the assembly 400 is processed so as to form a polycrystalline dielectric 204 from the dielectric 402. In some embodiments, the processing performed to form the polycrystalline dielectric 204 from the dielectric 402 may include annealing the dielectric 402. For example, the polycrystalline dielectric 204 may include titanium dioxide deposited at 300 degrees Celsius using ALD. In some embodiments, the grain boundaries spacing 216 of the grains 210 of the polycrystalline dielectric 204 may be approximately 50 nanometers, approximately 100 nanometers, approximately 200 nanometers, or greater. As noted above, in some embodiments, the processing represented by FIG. 5 may not be performed. The formed polycrystalline dielectric 204 may have an exposed surface 504.

FIG. 6 depicts an assembly 600 formed after a semiconductor material 602 is deposited on the surface 504 of the polycrystalline dielectric 204. In some embodiments, the semiconductor material 602 may be an amorphous material at the time of deposition, and may be subsequently processed to transform the semiconductor material 602 into a polycrystalline semiconductor material (as discussed below with reference to FIG. 7). For example, the semiconductor material 602 may be an amorphous semiconductor material sputter deposited onto the surface 504 of the polycrystalline dielectric 204. This sputter deposition may take place at approximately room temperature. In some embodiments, such sputter deposition may take place at a temperature between approximately 15 degrees Celsius and approximately 30 degrees Celsius. Sputter deposition may be an advantageous technique for depositing the semiconductor material 602, as it may be readily implemented in high volumes and large areas. Some processes, such as chemical vapor deposition (CVD), may not have precursors below 400 degrees Celsius, and thus such processes may not be suitable when working with many flexible substrates. In some embodiments, the semiconductor material 602 may include amorphous indium antimonide sputtered at approximately room temperature (e.g., 25 degrees Celsius).

In some embodiments, the semiconductor material 602 may be in polycrystalline form at the time of or substantially at the time of deposition, and thus may not need much or any further processing to form a polycrystalline semiconductor material. For example, in some embodiments, the semiconductor material 602 may be deposited onto the surface 504 of the polycrystalline dielectric 204 at a temperature between approximately 200 degrees Celsius and approximately 400 degrees Celsius. This high temperature deposition may result in a polycrystalline semiconductor material being formed on the surface 504 without substantial additional processing. In some embodiments, the polycrystalline dielectric 204 may be heated prior to deposition of the semiconductor material 602, and the heat of the polycrystalline dielectric 204 may be sufficient to result in a polycrystalline semiconductor material being formed on the surface 504 without substantial additional processing. In some embodiments, sputter deposition may be used to provide the semiconductor material 602 to a heated substrate (e.g., heated to a temperature of up to approximately 350 degrees Celsius to approximately 400 degrees Celsius).

FIG. 7 depicts the semiconductor assembly 200 (FIG. 2) formed after the assembly 600 is processed so as to form a polycrystalline semiconductor material 206 from the semiconductor material 602. In some embodiments, the processing performed to form the polycrystalline semiconductor material 206 from the semiconductor material 602 may include annealing the semiconductor material 602. For example, the polycrystalline semiconductor material 206 may be formed by a forming gas anneal at 400 degrees Celsius of a semiconductor material 602 including indium antimonide. And anneal may include a furnace anneal, a rapid thermal anneal, and/or a flash anneal, for example.

The time and temperature of anneal may be determined in accordance with routine techniques. For example, in some embodiments, the polycrystalline semiconductor material 602 may be formed of indium antimonide at a thickness of 500 nanometers, and the anneal may be performed at 400 degrees Celsius for five minutes. The processing illustrated in FIG. 7 may take place in a range of temperatures depending upon the semiconductor material 602, the underlying layers, the thickness of the semiconductor material 602, and stress in the semiconductor material 602, among others. In some embodiments, forming the polycrystalline semiconductor material 206 from the semiconductor material 602 may take place at a lower temperature when the semiconductor material 206 is deposited on the polycrystalline dielectric 204, as compared to deposition on an amorphous substrate, due to the increased number of nucleation sites provided by the polycrystalline dielectric 204.

In some embodiments, the semiconductor material 602 may be deposited by sputter deposition in an amorphous form, and the further processing may include laser melting the sputter deposited amorphous semiconductor material 602 to form the polycrystalline semiconductor material 206. Laser melting may involve using a high temperature laser process (e.g., greater than 1400 degrees Celsius) in a local area of the semiconductor material 602 such that the flexible substrate 202 may only experience temperatures of 200 degrees Celsius or less. Laser melting may be more appropriate for single compound materials, as the components of multiple compound materials may have vapor pressure differences that cause some of the components to evaporate during the laser process. Consequently, laser processes developed for single compound materials may not be readily suitable for multiple compound materials. In some embodiments, the evaporation of different compounds of a multiple compound material during laser melting may be mitigated by depositing a protective cap (e.g., silicon nitride or silicon oxide) on the multiple compound material, then removing the protective cap (e.g., by etching) after laser processing. As noted above, in some embodiments, the processing represented by FIG. 7 may not be performed.

During the processing of the semiconductor material 602 (e.g., as indicated in FIG. 7), the polycrystalline dielectric 204 may act as a nucleation layer for the crystallization of the semiconductor material 602 into the polycrystalline semiconductor material 206. In particular, the grain boundaries 208 of the polycrystalline dielectric 204 may provide heterogeneous nucleation sites for the crystallization of the grains 212 of the polycrystalline semiconductor material 206. Consequently, the size and pattern of the grains 212 of the polycrystalline semiconductor material 206 may be related to the size and pattern of the grains 210 of the polycrystalline dielectric 204. In particular, if the grains 210 of the polycrystalline dielectric 204 are of a substantially uniform size, the grains 212 of the polycrystalline semiconductor material 206 may also be substantially uniform. Greater uniformity in the size of the grains 212 on the polycrystalline semiconductor material 206 may provide improved electrical performance over less uniform materials. For example, in some embodiments in which the polycrystalline semiconductor material 206 includes indium antimonide, allowing the polycrystalline semiconductor material 206 to crystallize on a polycrystalline dielectric 204 may result in a sheet resistance that is less than 2000 ohms per square (e.g., for a polycrystalline semiconductor material having a thickness of approximately 500 nanometers). By comparison, allowing the polycrystalline semiconductor material 206 to crystallize directly on an amorphous material (e.g., glass) may result in a sheet resistance that is greater than 3000 ohms per square (e.g., for a polycrystalline semiconductor material having a thickness of approximately 500 nanometers).

Even if the incompatible temperature constraints of many semiconductor materials and flexible substrates could be overcome, flexible substrates may still not provide sufficiently regular nucleation sites for the formation of suitably regular polycrystalline semiconductor materials. The polycrystalline dielectric 204, interposed between the polycrystalline semiconductor material 206 and the flexible substrate 202, may provide the desired regular nucleation sites. Control of the density of the nucleation sites of the polycrystalline dielectric 204 (e.g., by control of the material included in the polycrystalline dielectric 204 in the conditions under which the grains of the polycrystalline dielectric 204 are formed) may enable the control of the density of grains 212 of the polycrystalline semiconductor material 206. For example, in some embodiments, increasing the temperature under which the polycrystalline dielectric 204 is formed may increase the size of the grains 210. In some embodiments, increasing the thickness of the polycrystalline dielectric 204 may result in crystallization at lower temperatures than would be achieved for thinner embodiments of the polycrystalline dielectric 204.

In some embodiments, the choice of material for the polycrystalline dielectric 204 and the choice of the material for the polycrystalline semiconductor material 206 may be linked. In particular, in some embodiments, these materials may be selected to have similar lattice constants and/or crystal structures. When so selected, the polycrystalline dielectric 204 may provide a “template” for formation of the grains 212 of the polycrystalline semiconductor material 206. The resulting polycrystalline semiconductor material 206 may have a textured (or preferred orientation) grain structure, providing improved electrical performance.

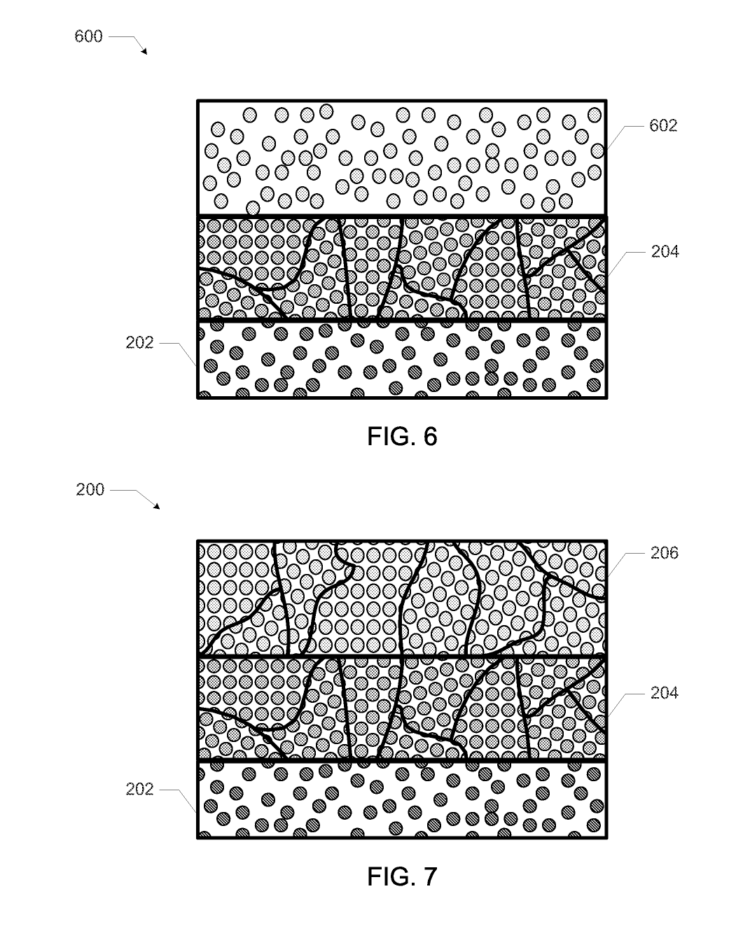

The semiconductor assemblies disclosed herein (such as the semiconductor assembly 200) may be used as a semiconductor substrate in electrical and/or optical circuit devices. In particular, devices, such as transistors, may be formed on and/or in the polycrystalline semiconductor material 206 in a manner analogous to conventional semiconductor circuit manufacture techniques (e.g., those performed on silicon or other semiconductor wafers). For example, the semiconductor assembly 200 may be included in a device layer of an IC device (e.g., as discussed below with reference to FIG. 8). However, because the semiconductor assembly 200 includes a flexible substrate 202, the semiconductor assembly 200 may be able to bend and otherwise to form in a manner not achievable by conventional rigid substrates (such as silicon wafers). Thus, the range of applications of the semiconductor assemblies disclosed herein may be broader than the range of applications of conventional rigid circuits.

Achievable mobilities may vary based on the material, process, and other variables. For example, in some embodiments, an indium antimonide material formed at a thickness of 500 nanometers, with an anneal performed at 400 degrees Celsius for five minutes (e.g., as discussed above with reference to the polycrystalline semiconductor material 602), may achieve a mobility of approximately 50 square centimeters per volt-second. Mobility may be a function of the charge carrier density, and mobility of a polycrystalline material may be a function of grain size (related to the number of scattering centers), grain orientation, and the angles at which grains meet, for example. Fabrication processes may be controlled to achieve desired properties.

The semiconductor assemblies and related techniques disclosed herein may be included in an IC device. FIG. 8 is a cross-sectional view of a portion of an IC device 800 including a device layer 818 (which may include one or more of the semiconductor assemblies disclosed herein), in accordance with various embodiments.

The IC device 800 may be formed on a substrate 804 (which may take the form of any of the semiconductor assemblies 200 disclosed herein). In particular, the substrate 804 may have a flexible substrate (such as the flexible substrate 202, a polycrystalline dielectric (such as the polycrystalline dielectric 204), and a polycrystalline semiconductor material (such as the polycrystalline semiconductor material 206). The semiconductor material of the substrate 804 may include, for example, N-type or P-type materials systems.

In some embodiments, the IC device 800 may include a device layer 818 disposed on the substrate 804. The device layer 818 may include channels providing features of one or more transistors 808 formed on the substrate 804. The device layer 818 may include, for example, one or more sources and/or drains (S/D) 810, a gate 812 to control current flow in the transistor(s) 808 between the S/D regions 810, and one or more S/D contacts 814 to route electrical signals to/from the S/D regions 810. The transistor(s) 808 may include additional features not depicted for the sake of clarity, such as device isolation regions, gate contacts, and the like. The transistor(s) 808 are not limited to the type and configuration depicted in FIG. 8 and may include a wide variety of other types and configurations, such as planar and non-planar transistors such as dual- or double-gate transistors, tri-gate transistors, and all-around gate (AAG) or wrap-around gate transistors, some of which may be referred to as FinFETs (Field Effect Transistors). In some embodiments, the device layer 818 may include one or more transistors or memory cells of a logic device or a memory device, or combinations thereof. In some embodiments, the device layer 818 may include optical devices. Polycrystalline semiconductor materials from the II-VI family may be particularly useful in optical applications.

Electrical signals such as, for example, power and/or input/output (I/O) signals may be routed to and/or from the transistor(s) 808 of the device layer 818 through one or more interconnect layers 820 and 822 disposed on the device layer 818. For example, electrically conductive features of the device layer 818 such as, for example, the gate 812 and S/D contacts 814 may be electrically coupled with the interconnect structures 816 of the interconnect layers 820 and 822. The interconnect structures 816 may be configured within the interconnect layers 820 and 822 to route electrical signals according to a wide variety of designs and are not limited to the particular configuration of interconnect structures 816 depicted in FIG. 8. For example, in some embodiments, the interconnect structures 816 may include trench structures (sometimes referred to as “lines”) and/or via structures (sometimes referred to as “holes”) filled with an electrically conductive material such as a metal. In some embodiments, the interconnect structures 816 may comprise copper or another suitable electrically conductive material. In some embodiments, optical signals may be routed to and/or from the device layer 818 instead of or in addition to electrical signals.

The interconnect layers 820 and 822 may include the dielectric layer 824 disposed between the interconnect structures 816, as can be seen. In some embodiments, a first interconnect layer 820 (referred to as Metal 1 or “M1”) may be formed directly on the device layer 818. In some embodiments, the first interconnect layer 820 may include some of the interconnect structures 816, which may be coupled with contacts (e.g., the S/D contacts 814) of the device layer 818.

Additional interconnect layers (not shown for ease of illustration) may be formed directly on the first interconnect layer 820 and may include interconnect structures 816 to couple with interconnect structures of the first interconnect layer 820.

The IC device 800 may have one or more bond pads 826 formed on the interconnect layers 820 and 822. The bond pads 826 may be electrically coupled with the interconnect structures 816 and configured to route the electrical signals of transistor(s) 808 to other external devices. For example, solder bonds may be formed on the one or more bond pads 826 to mechanically and/or electrically couple a chip including the IC device 800 with another component such as a circuit board. The IC device 800 may have other alternative configurations to route the signals from the interconnect layers 820 and 822 than depicted in other embodiments. In other embodiments, the bond pads 826 may be replaced by or may further include other analogous features (e.g., posts) that route the signals to other external components.

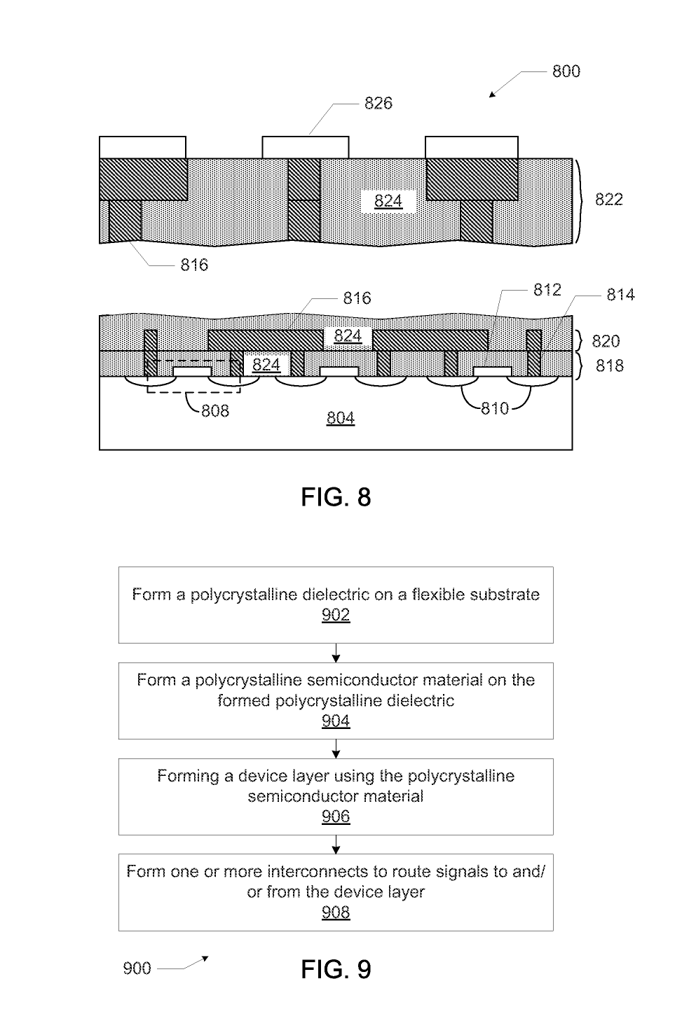

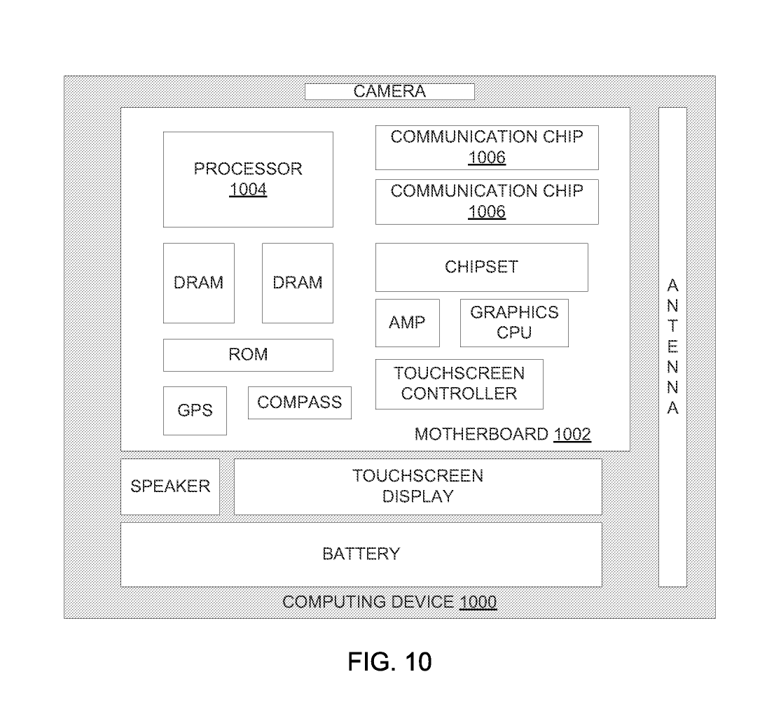

FIG. 9 is a flow diagram of an illustrative process 900 for manufacturing an IC device including a semiconductor assembly, in accordance with various embodiments. The operations of the process 900 may be discussed below with reference to the semiconductor assembly 200 (FIG. 2), but this is simply for ease of illustration, and the process 900 may be applied so as to form any suitable IC device. In some embodiments, the process 900 may be performed to manufacture an IC device included in the computing device 1000 discussed below with reference to FIG. 10. Various operations of the process 900 may be repeated, rearranged, or omitted as suitable.

At 902, a polycrystalline dielectric may be formed on a flexible substrate. In various embodiments, the polycrystalline dielectric may take the form of any of the embodiments of the polycrystalline dielectric 204 discussed above, and the flexible substrate may take the form of any of the embodiments of the flexible substrate 202 discussed above.

At 904, a polycrystalline semiconductor material may be formed on the polycrystalline dielectric formed at 902. In various embodiments, the polycrystalline semiconductor material may take the form of any of the embodiments of the polycrystalline semiconductor material 206 discussed above. In some embodiments, the process 900 may end at 904, and 906 and 908 (discussed below) may not be performed.

At 906, a device layer may be formed using the polycrystalline semiconductor material of 904. For example, one or more transistors or other devices may be formed in or on the polycrystalline semiconductor material of 904. The device layer formed at 906 may take the form of the device layer 818 discussed above with reference to FIG. 8, for example.

At 908, one or more interconnects may be formed to route signals to and/or from the device layer of 906. The interconnects formed at 908 may route electrical, optical and/or any other suitable signals to and/or from the device layer of 906. The interconnects formed at 908 may take the form of the interconnect structures 816 discussed above with reference to FIG. 8, for example. The process 900 may then end.

FIG. 10 schematically illustrates a computing device 1000 that may include one or more of the semiconductor assemblies 200 disclosed herein, in accordance with various embodiments. In particular, substrates of any suitable ones of the components of the computing device 1000 may include the semiconductor assemblies 200 disclosed herein.

The computing device 1000 may house a board such as motherboard 1002. The motherboard 1002 may include a number of components, including but not limited to a processor 1004 and at least one communication chip 1006. The processor 1004 may be physically and electrically coupled to the motherboard 1002. In some implementations, the at least one communication chip 1006 may also be physically and electrically coupled to the motherboard 1002. In further implementations, the communication chip 1006 may be part of the processor 1004. The term “processor” may refer to any device or portion of a device that processes electronic data from registers and/or memory to transform that electronic data into other electronic data that may be stored in registers and/or memory.

Depending on its applications, computing device 1000 may include other components that may or may not be physically and electrically coupled to the motherboard 1002. These other components may include, but are not limited to, volatile memory (e.g., dynamic random access memory), non-volatile memory (e.g., read-only memory), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, a Geiger counter, an accelerometer, a gyroscope, a speaker, a camera, and a mass storage device (such as hard disk drive, compact disk (CD), digital versatile disk (DVD), and so forth).

The communication chip 1006 may enable wireless communications for the transfer of data to and from the computing device 1000. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 1006 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as 3GPP2), etc.). IEEE 802.16 compatible BWA networks are generally referred to as WiMAX networks, an acronym that stands for Worldwide Interoperability for Microwave Access, which is a certification mark for products that pass conformity and interoperability tests for the IEEE 802.16 standards. The communication chip 1006 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1006 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1006 may operate in accordance with Code Division Multiple Access (CDMA), Time Division Multiple Access (TDMA), Digital Enhanced Cordless Telecommunications (DECT), Evolution-Data Optimized (EV-DO), derivatives thereof, as well as any other wireless protocols that are designated as 3G, 4G, 5G, and beyond. The communication chip 1006 may operate in accordance with other wireless protocols in other embodiments.

The computing device 1000 may include a plurality of communication chips 1006. For instance, a first communication chip 1006 may be dedicated to shorter range wireless communications such as Wi-Fi and Bluetooth and a second communication chip 1006 may be dedicated to longer range wireless communications such as GPS, EDGE, GPRS, CDMA, WiMAX, LTE, EV-DO, and others.

The communication chip 1006 may also include an IC package assembly that may include a semiconductor assembly as described herein. In further implementations, another component (e.g., memory device, processor or other integrated circuit device) housed within the computing device 1000 may contain a semiconductor assembly as described herein.

In various implementations, the computing device 1000 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 1000 may be any other electronic device that processes data. In some embodiments, the techniques described herein are implemented in a high-performance computing device. In some embodiments, the techniques described herein are implemented in handheld computing devices.

The following paragraphs provide a number of examples of the embodiments disclosed herein. Example 1 is a semiconductor assembly, including: a flexible substrate; a polycrystalline semiconductor material comprising a polycrystalline III-V material, a polycrystalline II-VI material or polycrystalline germanium; and a polycrystalline dielectric disposed between and adjacent to the flexible substrate and the polycrystalline semiconductor material.

Example 2 may include the subject matter of Example 1, and may further specify that grain boundaries of the polycrystalline dielectric are nucleation sites for grains of the polycrystalline semiconductor material.

Example 3 may include the subject matter of Example 2, and may further specify that at least some of the grain boundaries of the polycrystalline dielectric are spaced apart by a distance between approximately 50 nanometers and approximately 200 nanometers.

Example 4 may include the subject matter of any of Examples 1-3, and may further specify that the flexible substrate comprises an amorphous material.

Example 5 may include the subject matter of any of Examples 1-4, and may further specify that the flexible substrate comprises polyethylene terephthalate, polyethylene naphthalate, polycarbonate material, polyethersulfone material, polyimide material, or alkali-free borosilicate.

Example 6 may include the subject matter of any of Examples 1-5, and may further specify that the polycrystalline dielectric comprises titanium dioxide, silicon dioxide or aluminum oxide.

Example 7 may include the subject matter of any of Examples 1-6, and may further specify that the polycrystalline semiconductor material has a thickness between approximately 5 nanometers and approximately 250 nanometers.

Example 8 may include the subject matter of any of Examples 1-7, and may further specify that the polycrystalline semiconductor material comprises polycrystalline indium antimonide.

Example 9 may include the subject matter of Example 1, and may further specify that a sheet resistance of the polycrystalline semiconductor material is less than 2000 ohms per square when the polycrystalline semiconductor material has a thickness of 500 nanometers.

Example 10 may include the subject matter of Example 1, and may further specify that the flexible substrate has a melting temperature less than 400 degrees Celsius.

Example 11 is a method for manufacturing a semiconductor assembly, including: forming a polycrystalline dielectric on a flexible substrate; and forming a polycrystalline semiconductor material on the polycrystalline dielectric, wherein the polycrystalline semiconductor material comprises a polycrystalline III-V material, a polycrystalline II-VI material or polycrystalline germanium.

Example 12 may include the subject matter of Example 11, and may further specify that forming the polycrystalline dielectric comprises atomic layer deposition of the polycrystalline dielectric.

Example 13 may include the subject matter of Example 11, and may further specify that forming the polycrystalline dielectric comprises spinning on the polycrystalline dielectric.

Example 14 may include the subject matter of any of Examples 11-13, and may further specify that forming the polycrystalline semiconductor material on the polycrystalline dielectric includes: sputter depositing an amorphous semiconductor material on the polycrystalline dielectric; and annealing the amorphous semiconductor material to form the polycrystalline semiconductor material.

Example 15 may include the subject matter of Example 14, and may further specify that sputter depositing the amorphous semiconductor material on the polycrystalline dielectric includes sputter depositing the amorphous semiconductor material on the polycrystalline dielectric at a temperature between approximately 15 degrees Celsius and approximately 30 degrees Celsius.

Example 16 may include the subject matter of Example 11, and may further specify that forming the polycrystalline semiconductor material on the polycrystalline dielectric includes: heating the polycrystalline dielectric; and depositing an amorphous semiconductor material on the polycrystalline dielectric to form the polycrystalline semiconductor material.

Example 17 may include the subject matter of Example 11, and may further specify that forming the polycrystalline semiconductor material on the polycrystalline dielectric includes depositing an amorphous semiconductor material on the polycrystalline dielectric at a temperature between approximately 200 degrees Celsius and approximately 400 degrees Celsius to form the polycrystalline semiconductor material.

Example 18 may include the subject matter of Example 11, and may further specify that forming the polycrystalline semiconductor material on the polycrystalline dielectric includes: sputter depositing an amorphous semiconductor material on the polycrystalline dielectric; and laser melting the amorphous semiconductor material to form the polycrystalline semiconductor material.

Example 19 is an IC device, including: a flexible substrate; a device layer, comprising one or more transistors formed on a polycrystalline semiconductor material comprising a polycrystalline III-V material, a polycrystalline II-VI material or polycrystalline germanium; a polycrystalline dielectric disposed between and adjacent to the flexible substrate and the polycrystalline semiconductor material; and one or more interconnects routing electrical signals to and/or from the device layer.

Example 20 may include the subject matter of Example 19, and may further specify that the polycrystalline semiconductor material forms a channel in a transistor of the device layer.

Example 21 may include the subject matter of any of Examples 19-20, and may further specify that the polycrystalline semiconductor material comprises a polycrystalline III-nitride material.

Example 22 may include the subject matter of Example 21, and may further specify that the polycrystalline dielectric comprises aluminum oxide.

Example 23 may include the subject matter of Example 21, and may further specify that the polycrystalline dielectric comprises silicon carbide.

Example 24 may include the subject matter of any of Examples 19-23, and may further specify that the flexible substrate has a melting temperature less than 400 degrees Celsius.

1. A semiconductor assembly, comprising:
a flexible substrate;
a polycrystalline semiconductor material comprising a polycrystalline III-V material, a polycrystalline II-VI material or polycrystalline germanium; and
a polycrystalline dielectric disposed between and adjacent to the flexible substrate and the polycrystalline semiconductor material.

2. The semiconductor assembly of claim 1, wherein grain boundaries of the polycrystalline dielectric are nucleation sites for grains of the polycrystalline semiconductor material.

3. The semiconductor assembly of claim 2, wherein at least some of the grain boundaries of the polycrystalline dielectric are spaced apart by a distance between approximately 50 nanometers and approximately 200 nanometers.

4. The semiconductor assembly of claim 1, wherein the flexible substrate comprises an amorphous material.

5. The semiconductor assembly of claim 1, wherein the flexible substrate comprises polyethylene terephthalate, polyethylene naphthalate, polycarbonate material, polyethersulfone material, polyimide material, or alkali-free borosilicate.

6. The semiconductor assembly of claim 1, wherein the polycrystalline dielectric comprises titanium dioxide, silicon dioxide or aluminum oxide.

7. The semiconductor assembly of claim 1, wherein the polycrystalline semiconductor material has a thickness between approximately 5 nanometers and approximately 250 nanometers.

8. The semiconductor assembly of claim 1, wherein the polycrystalline semiconductor material comprises polycrystalline indium antimonide.

9. The semiconductor assembly of claim 1, wherein a sheet resistance of the polycrystalline semiconductor material is less than 2000 ohms per square when the polycrystalline semiconductor material has a thickness of 500 nanometers.

10. The semiconductor assembly of claim 1, wherein the flexible substrate has a melting temperature less than 400 degrees Celsius.

11. A method for manufacturing a semiconductor assembly, comprising:
forming a polycrystalline dielectric on a flexible substrate; and
forming a polycrystalline semiconductor material on the polycrystalline dielectric, wherein the polycrystalline semiconductor material comprises a polycrystalline III-V material, a polycrystalline II-VI material or polycrystalline germanium.

12. The method of claim 11, wherein forming the polycrystalline dielectric comprises atomic layer deposition of the polycrystalline dielectric.

13. The method of claim 11, wherein forming the polycrystalline dielectric comprises spinning on the polycrystalline dielectric.

14. The method of claim 11, wherein forming the polycrystalline semiconductor material on the polycrystalline dielectric comprises:
sputter depositing an amorphous semiconductor material on the polycrystalline dielectric; and
annealing the amorphous semiconductor material to form the polycrystalline semiconductor material.

15. The method of claim 14, wherein sputter depositing the amorphous semiconductor material on the polycrystalline dielectric comprises:
sputter depositing the amorphous semiconductor material on the polycrystalline dielectric at a temperature between approximately 15 degrees Celsius and approximately 30 degrees Celsius.

16. The method of claim 11, wherein forming the polycrystalline semiconductor material on the polycrystalline dielectric comprises:
heating the polycrystalline dielectric; and
depositing an amorphous semiconductor material on the polycrystalline dielectric to form the polycrystalline semiconductor material.

17. The method of claim 11, wherein forming the polycrystalline semiconductor material on the polycrystalline dielectric comprises:
depositing an amorphous semiconductor material on the polycrystalline dielectric at a temperature between approximately 200 degrees Celsius and approximately 400 degrees Celsius to form the polycrystalline semiconductor material.

18. The method of claim 11, wherein forming the polycrystalline semiconductor material on the polycrystalline dielectric comprises:
sputter depositing an amorphous semiconductor material on the polycrystalline dielectric; and
laser melting the amorphous semiconductor material to form the polycrystalline semiconductor material.

19. An integrated circuit (IC) device, comprising:
a flexible substrate;
a device layer, comprising one or more transistors formed on a polycrystalline semiconductor material comprising a polycrystalline III-V material, a polycrystalline II-VI material or polycrystalline germanium;
a polycrystalline dielectric disposed between and adjacent to the flexible substrate and the polycrystalline semiconductor material; and
one or more interconnects routing electrical signals to and/or from the device layer.

20. The IC device of claim 19, wherein the polycrystalline semiconductor material forms a channel in a transistor of the device layer.

21. The IC device of claim 19, wherein the polycrystalline semiconductor material comprises a polycrystalline III-nitride material.

22. The IC device of claim 21, wherein the polycrystalline dielectric comprises aluminum oxide.

23. The IC device of claim 21, wherein the polycrystalline dielectric comprises silicon carbide.

24. The IC device of claim 19, wherein the flexible substrate has a melting temperature less than 400 degrees Celsius.
